(19) United States
(12) Patent Application Publication
(10) Pub. No.: US 2017/0138999 A1
(43) Pub. Date: May 18, 2017

(54) ARC FLASH DETECTION DEVICE HAVING OPTIC FIBER SENSOR

(71) Applicant: G2 Power Co., Ltd., Gyeonggi-do (KR)

(72) Inventor: Young il KIM, Gyeonggi-do (KR)

(21) Appl. No.: 14/939,204

(22) Filed: Nov. 12, 2015

(51) Int. Cl. G01R 31/12

(52) U.S. Cl. CPC G01R 31/1272

(57) ABSTRACT

The present invention relates to an arc flash detection device for detecting the generation of an arc flash in a power receiving and distributing facility and for generating a trip signal upon the generation of the arc flash, including: optical fiber cables for transmitting an arc flash detection optical signal and receiving an arc flash optical signal converted by the arc flash; a lens part having a reflection element adapted to reflect the arc flash detection optical signal transmitted through the optical fiber cables and the arc flash optical signal converted by the arc flash if the arc flash is generated; and an optical detection part for transmitting the arc flash detection optical signal through the optical fiber cables and comparing the arc flash optical signal received through the lateral periphery of one side optical fiber cable and the arc flash optical signal reflected on the lens part with the arc flash detection optical signal to output an arc flash generation signal as a difference signal between the compared results.

### BACKGROUND OF THE INVENTION

Field of the Invention

The present invention relates to an arc flash detection device and method that detects an arc flash in high and low voltage distribution panels, a motor control panel, and a panel board (which are referred to as “power receiving and distributing facility”) in which high and low voltage electricity is received and distributed, and more particularly, to an arc flash detection device and method that is provided with an optical system having a line sensor and a loop sensor to detect an arc flash.

Background of the Related Art

In various workplaces like factories, schools and buildings, equipment, which works with power supplied thereto, generally includes a body for supplying the power, a work machine for receiving the power from the body to really perform a given work, and a cable for transmitting the power from the body to the work machine.

In most workplaces, the body and the work machine of the equipment are separated from each other at a relatively long distance. Further, there is a central monitoring station for sensing the state of power consumed at the workplace, monitoring fire occurrence dangers due to the overload at the workplace, and allowing the monitoring result to be recognized to a worker staying at the workplace, so that an appropriate action is taken by the worker to avoid the occurrence of fires.

Like this, the worker who receives the monitoring result from the central monitoring station should always stay at the workplace so as to monitor the state of power, which raises the labor cost, and further, if an appropriate action is not taken by the worker, power loss and huge fire disasters may happen.

A power receiving and distributing facility includes various kinds of terminals, bus-bars and the like, and accordingly, the power receiving and distributing facility is necessarily provided with an insulation box, a power receiving panel body, and a distributing panel body that have openable and closable doors adapted to limit the direct contact with the outside and to conduct interior checking or maintenance in consideration of the stability from the electric shock of a human body and fire occurrence during the use of the facility, and with various protection equipment like a circuit breaker and a lightning arrester disposed in the box in consideration of the reliability of continuous and uniform supply voltage.

So as to prevent fire and/or power failure accidents from happening on a power receiving panel, a distribution panel, and a motor control panel, safety check or maintenance for the power receiving and distributing facility should be frequently carried out.

Such safety check and maintenance causes a manager or worker to approach the power receiving and distributing facility by a given distance. So as to conduct the safety check and maintenance, moreover, the manager or worker approaches the power receiving and distributing facility being in a live cable state. As a result, the manager or worker may be electrically shocked, and further, various safety accidents may frequently happen.

So as to prevent the occurrence of safety accidents, accordingly, there is proposed Korean Patent Registration No. 10-1194708 (which is referred to as ‘Patent Document 1’) disclosing a power receiving and distributing facility having a power shielding function through arc flash sensing. According to Patent Document 1, the conventional power receiving and distributing facility senses the approaching distance of a worker through an approaching sensor, senses an arc flash through an arc sensor, measures quantities of used current of loads through current sensors, calculates arc flash accident energy levels in consideration of the sensed and measured results and the space of a panel board, selectively applies a control signal to a trip coil of a circuit breaker according to the calculated arc flash accident energy levels, and controls the supply and cutoff of the power.

On the other hand, the power receiving and distributing facility can continuously supply power even to equipment using arc like a welding machine used therearound and an electric furnace used to melt metal. The arc flash generated in such equipment using arc have the same or similar wavelengths as or to those generated in the power receiving and distributing facility. Accordingly, the normal arc flash (that is, the arc flash generated at the outside) generated by normal causes may be erroneously sensed as the arc flash generated due to accidents or insulation deterioration from the interior of the power receiving and distributing facility. Accordingly, the power receiving and distributing facility in Patent Document 1 may drive the circuit breaker or issue a danger warning unnecessarily. As a result, power failure is unnecessarily done, thus making it hard to conduct the maintenance of the power receiving and distributing facility and the normal operation of the loads.

So as to solve the problems occurring in Patent Document 1, there is proposed Korean Patent Registration No. 10-1197021 (which is referred to as ‘Patent Document 2’) disclosing a power receiving and distributing facility having an arc flash sensor capable of correctly sensing the position at which an arc flash is generated. According to Patent Document 2, the arc flash sensor of the power receiving and distributing facility includes an optical fiber and a fluorescent filter to block unnecessary ultraviolet rays introducible thereinto. That is, only the arc flash generated from the interior region where the arc flash may be generated can be sensed by the arc flash sensor. Accordingly, the power receiving and distributing facility in Patent Document 2 provides many conveniences in the maintenance thereof.

Further, there is proposed Korean Patent Application Laid-open No. 2011-0001943 (which is referred to as ‘Patent Document 3’) disclosing an arc flash detector as shown in FIG. 1. According to Patent Document 3, the arc flash detector includes an optical attenuation filter 1, an optical sensor 2 and a logical circuit 3, and if surrounding light is inputted to the optical attenuation filter 1 for attenuating air light to a previously determined ratio, the attenuated surrounding light is transmitted from the optical attenuation filter 1 to the optical sensor 2. If the attenuated surrounding light has an enough strength to saturate the optical sensor 2, the optical sensor 2 outputs an output signal to the logical circuit 3, and the logical circuit 3 estimates the output signal of the optical sensor 2, so that if it is determined that an arc flash event is generated, the logical circuit 3 generates an output signal therefrom. The output signal of the logical circuit 3 stops the arc flash, and the generation of the arc flash is recognized to a worker to take an appropriate action.

According to the above-mentioned conventional practice, however, even if the optical fiber and the fluorescent filter are mounted on the arc flash sensor, it is extremely difficult to completely block the outside light introducible to the arc flash sensor according to the characteristics of light. On the other hand, separate devices for perfectly blocking the outside light may be disposed on the power receiving and distributing facility, but the distance between the devices disposed in the power receiving and distributing facility may be decreased to give bad influences on the insulation properties of the power receiving and distributing facility and to increase the volume of the power receiving and distributing facility.

Further, the power receiving and distributing facilities according to Patent Documents 1 and 2 may be installed at various work environments including indoor and outdoor places. Accordingly, the luminance around the power receiving and distributing facilities may be varied according to the installation places and time. The varied surrounding luminance does not give any influence on sensing whether the arc flash having a wavelength of 300 to 1500 nm and luminance of about 9000 lux is generated or not, but gives an influence on the strength of the arc flash sensed by the sensor. As a result, the power receiving and distributing facilities according to Patent Documents 1 and 2 cannot precisely detect the strength of the arc flash, thus unnecessarily causing the circuit breaker to be driven or issuing the danger warning. Accordingly, power failure is unnecessarily done, thus making it hard to conduct the maintenance of the power receiving and distributing facility and the normal operation of the loads.

### SUMMARY OF THE INVENTION

Accordingly, the present invention has been made in view of the above-mentioned problems occurring in the prior art, and it is an object of the present invention to provide an arc flash detection device and method that is capable of detecting an arc flash in a power receiving and distributing facility having a power receiving panel, a distribution panel, a motor control panel, a high voltage panel, a low voltage panel, and a panel board to protect the power receiving and distributing facility from the danger of the arc flash.

It is another object of the present invention to provide an arc flash detection device and method that is capable of in advance preventing an arc flash from occurring in a power receiving and distributing facility, thus gently operating a power facility and ensuring the stability and reliability of the power receiving and distributing facility.

To accomplish the above-mentioned objects, according to a first aspect of the present invention, there is provided an arc flash detection device for detecting the generation of an arc flash in a power receiving and distributing facility in which a power receiving panel, a distribution panel, a motor control panel, a high voltage panel, a low voltage panel, and a panel board are disposed and for generating a trip signal upon the generation of the arc flash, including: optical fiber cables for transmitting an arc flash detection optical signal and receiving an arc flash optical signal converted by the arc flash; a lens part having a reflection element adapted to reflect the arc flash detection optical signal transmitted through the optical fiber cables and the arc flash optical signal converted by the arc flash if the arc flash is generated; and an optical detection part for transmitting the arc flash detection optical signal through the optical fiber cables and comparing the arc flash optical signal received through the lateral periphery of one side optical fiber cable and the arc flash optical signal reflected on the lens part with the arc flash detection optical signal to output an arc flash generation signal as a difference signal between the compared results.

According to the present invention, desirably, the optical detection part includes a line sensor, to which each optical fiber cable is connected, for detecting the arc flash on the end of the optical fiber cable, and a loop sensor for detecting the arc flash optical signal incident on the lateral periphery of the optical fiber cable disposed on the continuous section and transmitting the detected arc flash optical signal to a relay.

According to the present invention, desirably, each optical fiber cable is one strand of optical fiber made of a plastic optical fiber having a larger core than cladding.

According to the present invention, desirably, the loop sensor has a lateral light-receiving optical receiver for receiving the arc flash optical signal through the lateral periphery of the optical fiber.

According to the present invention, desirably, the optical fiber cables are scratched on one end thereof to form fine patterns therealong.

According to the present invention, desirably, each optical fiber cable has an ultraviolet absorbing material applied to the cladding thereof.

According to the present invention, desirably, the optical detection part includes a first optical detector and a second optical detector having the opposite phase to the first optical detector.

To accomplish the above-mentioned objects, according to a second aspect of the present invention, there is provided an arc flash detection method for detecting the generation of arc flash in a power receiving and distributing facility in which a power receiving panel, a distribution panel, a motor control panel, a high voltage panel, a low voltage panel, and a panel board are disposed and for generating a trip signal upon the generation of the arc flash, including the steps of: measuring the outputs of channels Ch+ and Ch− of a balanced detector; comparing the values of the measured channel outputs and outputting a difference value between the channels; comparing the difference value with previously set optical receiving sensitivity, and if the difference value is more than the set optical receiving sensitivity, determining that an arc flash is generated.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a block diagram showing a basic configuration of a conventional arc flash detection device;

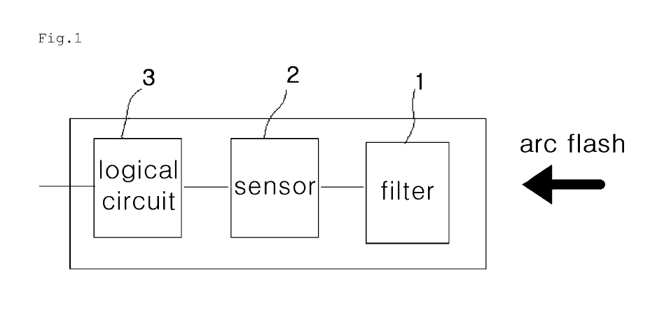

FIG. 2 is a perspective view showing a power receiving and distributing facility in which an arc flash detection device according to the present invention is disposed;

FIG. 3 is a detailed block diagram showing a collection module of FIG. 2;

FIG. 4 is a block diagram showing the arc flash detection device according to the present invention;

FIG. 5 is a sectional view showing an example of a structure for receiving light from the lateral periphery of an optical fiber cable in the arc flash detection device according to the present invention;

FIG. 6 is a sectional view showing another example of a structure for receiving light from the lateral periphery of an optical fiber cable in the arc flash detection device according to the present invention;

FIG. 7 is a graph showing the comparison between output voltages of an optical fiber cable being in a normal state and an optical fiber cable having a scratched fine pattern formed thereon, on a point of 20 m;

FIG. 8 is a graph showing the comparison between output voltages of the arc flash discharge according to the distance between an optical fiber and an arc light source;

FIG. 9 is a graph showing the comparison results of optical detection voltages according to arc discharge time;

FIG. 10 is a block diagram showing an optical transmitter disposed in an optical detection part of the arc flash detection device according to the present invention;

FIG. 11 is a circuit diagram showing the optical transmitter in an arc flash loop sensor;

FIG. 12 is a block diagram showing an optical receiver having a photodiode for detecting the light on the lateral periphery of the optical fiber according to the present invention;

FIG. 13 is a circuit diagram showing the optical receiver in an arc flash loop sensor;

FIG. 14 is a circuit diagram showing an arc flash line sensor;

FIG. 15 is a photograph showing the products of the arc flash loop sensor and the arc flash line sensor;

FIG. 16 is a diagram showing a basic configuration of an arc flash detection device using a balanced detector; and

FIG. 17 is a flowchart showing an arc flash detection algorism using the balanced detector of FIG. 16.

### DETAILED DESCRIPTION OF THE PREFERRED EMBODIMENTS

Hereinafter, an explanation on an arc flash detection device and method according to the present invention will be in detail given with reference to the attached drawing.

The present invention may be modified in various ways and may have several exemplary embodiments. Specific exemplary embodiments of the present invention are illustrated in the drawings and described in detail in the detailed description. However, this does not limit the invention within specific embodiments and it should be understood that the invention covers all the modifications, equivalents, and replacements within the idea and technical scope of the invention.

Terms, such as the first, the second, A, and B, may be used to describe various elements, but the elements should not be restricted by the terms. The terms are used to only distinguish one element from the other element. For example, a first element may be named a second element without departing from the scope of the present invention. Likewise, a second element may be named a first element. A term ‘and/or’ includes a combination of a plurality of relevant and described items or any one of a plurality of related and described items.

When it is said that one element is described as being “connected” or “coupled” to the other element, one element may be directly connected or coupled to the other element, but it should be understood that another element may be present between the two elements. In contrast, when it is said that one element is described as being “directly connected” or “directly coupled” to the other element, it should be understood that another element is not present between the two elements.

Terms used in this application are used to only describe specific exemplary embodiments and are not intended to restrict the present invention. An expression referencing a singular value additionally refers to a corresponding expression of the plural number, unless explicitly limited otherwise by the context. In this application, terms, such as “comprise”, “include”, or ‘have”, are intended to designate those characteristics, numbers, steps, operations, elements, or parts which are described in the specification, or any combination of them that exist, and it should be understood that they do not preclude the possibility of the existence or possible addition of one or more additional characteristics, numbers, steps, operations, elements, or parts, or combinations thereof.

All terms used herein, including technical or scientific terms, unless otherwise defined, have the same meanings which are typically understood by those having ordinary skill in the art. The terms, such as ones defined in common dictionaries, should be interpreted as having the same meanings as terms in the context of pertinent technology, and should not be interpreted as having ideal or excessively formal meanings unless clearly defined in the specification.

Exemplary embodiments of the present invention will be described in detail below with reference to the accompanying drawings. In order to facilitate the general understanding of the present invention in describing the present invention, through the accompanying drawings, the same reference numerals will be used to describe the same components and an overlapped description of the same components will be omitted.

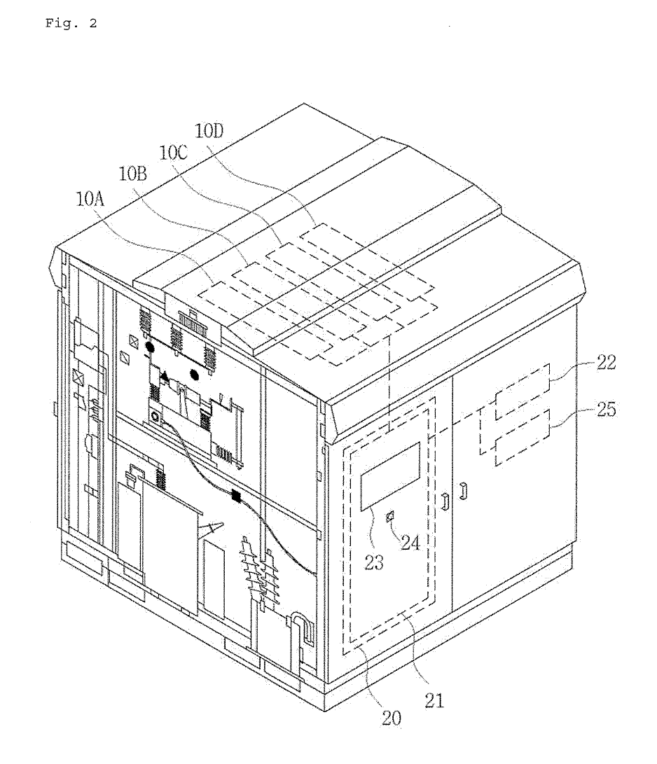

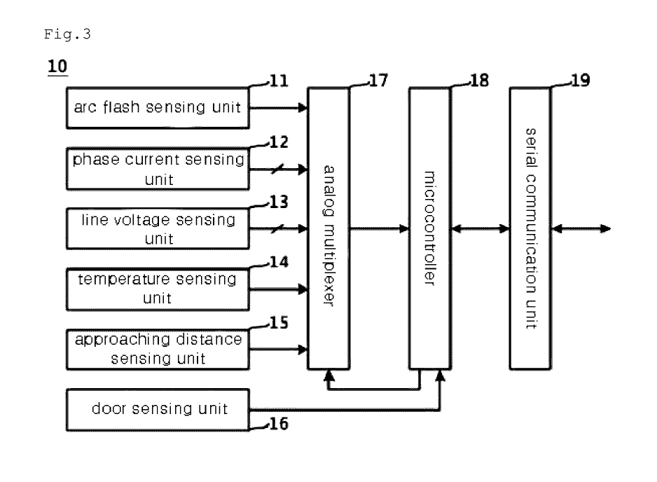

Referring to FIGS. 2 and 3, an example of a power receiving and distributing facility in which an arc flash detection device having an optical sensor according to the present invention is disposed will be explained.

FIG. 2 is a perspective view showing a power receiving and distributing facility in which an arc flash detection device according to the present invention is disposed, and FIG. 3 is a detailed block diagram showing a collection module of FIG. 2.

As shown in FIG. 2, the power receiving and distributing facility, in which an arc flash detection device according to the present invention is disposed, includes first to fourth collection modules 10A to 10D arranged correspondingly on accommodation spaces thereof, but does not necessarily include the first to fourth collection modules 10A to 10D. That is, as the number of accommodation spaces of the power receiving and distributing facility is increased or decreased, the number of collection modules may be increased and decreased. Further, the power receiving and distributing facility may include a diagnosis/cutoff module 20 for receiving the collection data from the first to fourth collection modules 10A to 10D.

The first collection module 10A is disposed in a first accommodation space of the power receiving and distributing facility. The second collection module 10B in a second accommodation space of the power receiving and distributing facility. The third collection module 10C in a third accommodation space of the power receiving and distributing facility. The fourth collection module 10D in a fourth accommodation space of the power receiving and distributing facility.

The first to fourth collection modules 10A to 10D may sense arc flashes generated in their corresponding accommodation spaces, temperatures in their corresponding accommodation spaces, and opening/closing states of the doors of their corresponding accommodation spaces. Further, each of the first to fourth collection modules 10A to 10D senses three-phase currents (that is, R phase current, S phase current and T phase current), symmetrical three-phase short circuit currents, and three line voltages (that is, R-S line voltage, S-T line voltage and T-R line voltage), which are received and distributed by means of a power receiving and distributing module in the corresponding accommodation space. Furthermore, the first to fourth collection modules 10A to 10D may sense distances (hereinafter, referred to as ‘approaching distance’) from an approaching object (for example, a manager or operator) approaching their corresponding accommodation spaces. The arc flash sensing signals, the temperature sensing signals, the door sensing signals, the phase current sensing signals, the symmetrical three-phase short circuit sensing signals, the line voltage sensing signals, and the approaching distance sensing signals generated from the first to fourth collection modules 10A to 10D may be transmitted to the diagnosis/cutoff module 20 in a form of digital data. So as to transmit the sensing signals, the first to fourth collection modules 10A to 10D are connected commonly to the diagnosis/cutoff module 20 by means of a serial bus. For example, the first to fourth collection modules 10A to 10D are connected commonly to the diagnosis/cutoff module 20 by means of an RS-485 MODBUS. Each of the first to fourth collection modules 10A to 10D is configured as shown in FIG. 3.

FIG. 3 is a detailed block diagram showing one of the collection modules of FIG. 2.

Referring to FIG. 3, the collection module 10 includes an arc flash sensing unit 11, a phase current sensing unit 12, a line voltage sensing unit 13, a temperature sensing unit 14, an approaching distance sensing unit 15, a door sensing unit 16, an analog multiplexer 17, a microcontroller 18 and a serial communication unit 19.

The arc flash sensing unit 11, in which the arc flash detection device according to the present invention is disposed, generates an arc offset voltage according to the luminance of the accommodation space. Further, the arc flash sensing unit reliably senses the arc flash generated in the accommodation space by using the arc offset voltage. The arc flash sensing signal generated from the arc flash sensing unit 11 is supplied to the microcomputer 18 via the analog multiplexer 17. The arc flash sensing unit 11 will be in detail described later.

The phase current sensing unit 12 senses the currents flowing through the R, S and T-phase voltage lines (not shown) in the accommodation space. Further, the phase current sensing unit 12 supplies the three-phase current sensing signals (that is, R, S, and T-phase current sensing signals) and the symmetrical three-phase short circuit sensing signals to the microcomputer 18 via the analog multiplexer 17. The three-phase current sensing signals and the symmetrical three-phase short circuit sensing signals may have the values more reduced by hundreds to thousands of times than the real phase currents and short circuit currents. The phase current sensing unit 12 is configured with a well known circuit having hall elements arranged on the R, S, and T-phase voltage lines and buffers connected correspondingly to the voltage lines.

The line voltage sensing unit 13 senses the line voltage between the R, S and T-phase voltage lines in the accommodation space. Further, the line voltage sensing unit 13 supplies the three line voltage sensing signals (that is, R-S line voltage, S-T line voltage and T-R line voltage) to the microcomputer 18 via the analog multiplexer 17. The line voltage sensing signals may have the values more reduced by hundreds to thousands of times than the real line voltages. The line voltage sensing unit 13 is configured with a well known circuit having transformers connected among the R, S, and T-phase voltage lines and buffers connected correspondingly to the transformers.

The temperature sensing unit 14 senses the temperature in the accommodation space. Further, the temperature sensing unit 14 supplies the temperature sensing signal to the microcomputer 18 via the analog multiplexer 17. The temperature sensing unit 14 is configured with a well known circuit having a temperature sensor and a buffer connected to the temperature sensor.

The approaching distance sensing unit 15 senses the approaching distance from someone approaching the accommodation space. Further, the approaching distance sensing unit 15 supplies the approaching distance sensing signal to the microcomputer 18 via the analog multiplexer 17. The approaching distance sensing unit 15 is configured with a well known circuit having an approaching distance sensor and a buffer connected to the approaching distance sensor.

The door sensing unit 16 senses the opening and closing state of the door in the accommodation space. Further, the door sensing unit 16 supplies the door sensing signal to the microcomputer 18 via the analog multiplexer 17. The door sensing unit 16 is configured with a well known circuit having a contact switch turned on/off according to the opening and closing of the door in the accommodation space and a buffer buffering the output signal of the contact switch to a form of a logical value.

The analog multiplexer 17 selectively supplies the arc flash sensing signal from the arc flash sensing unit 11, the phase current sensing signals from the phase current sensing unit 12, the line voltage sensing signals from the line voltage sensing unit 13, the temperature sensing signal from the temperature sensing unit 14, and the approaching distance sensing signal from the approaching distance sensing unit 15 to the microcontroller 18. The selection operation of the analog multiplexer 17 is controlled by a four-bit selection signal of the microcontroller 18.

The microcontroller 18 cyclically changes the logical value of the selection signal supplied to the analog multiplexer 17 therefrom to cyclically scan the arc flash sensing signal from the arc flash sensing unit 11, the phase current sensing signals from the phase current sensing unit 12, the line voltage sensing signals from the line voltage sensing unit 13, the temperature sensing signal from the temperature sensing unit 14, and the approaching distance sensing signal from the approaching distance sensing unit 15. Further, the microcontroller 18 converts the analog voltages of the arc flash sensing signal, the phase current sensing signals, the line voltage sensing signals, the temperature sensing signal, and the approaching distance sensing signal cyclically inputted from the analog multiplexer 17 into digital numbers and temporarily stores the converted signals therein. Furthermore, the microcontroller transmits the arc flash sensing signal, the phase current sensing signals, the line voltage sensing signals, the temperature sensing signal, and the approaching distance sensing signal converted and stored therein and the door sensing signal generated from the door sensing unit 16 to the diagnosis/cutoff module 20 via the serial communication unit 19. Moreover, if the microcontroller 18 receives a data transmission request command having a unique address issued thereto from the serial communication unit 19, it transmits the sensing signals to the diagnosis/cutoff module 20. The microcontroller 18 includes an analog to digital (hereinafter, referred to as AD) converter for performing the analog to digital conversion of the analog sensing signals and a memory for temporarily storing the converted sensing signals.

The serial communication unit 19 transmits the data transmission request command from the diagnosis/cutoff module 20 to the microcontroller 18. Further, the serial communication unit 19 transmits the sensing signals from the microcontroller 18 to the diagnosis/cutoff module 20.

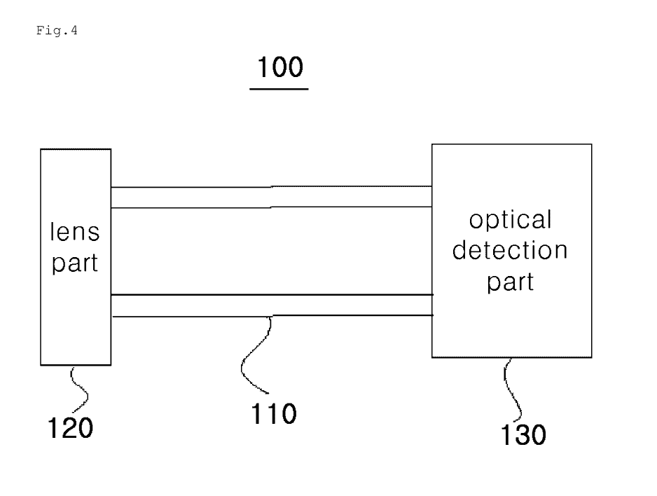

A basic configuration of the arc flash detection device according to the present invention will be explained with reference to FIG. 4.

FIG. 4 is a block diagram showing the arc flash detection device according to the present invention.

As shown in FIG. 4, the arc flash detection device 100 according to the present invention, which detects the generation of an arc flash in a power receiving and distributing facility in which a power receiving panel, a distribution panel, a motor control panel, a high voltage panel, a low voltage panel, and a panel board are disposed and generates a trip signal upon the generation of the arc flash, including: optical fiber cables 110 for transmitting an arc flash detection optical signal and receiving arc flash optical signals converted by the arc flash; a lens part 120 having a reflection element adapted to reflect the arc flash detection optical signal transmitted through the optical fiber cables 110 and to reflect the arc flash optical signals converted by the arc flash if the arc flash is generated; and an optical detection part 130 for transmitting the arc flash detection optical signal through the optical fiber cables 110 and comparing the arc flash optical signal received through the lateral periphery of one side optical fiber cable 120 and the arc flash optical signal reflected on the lens part 120 with the arc flash detection optical signal to output an arc flash generation signal as a difference signal between the compared results.

There is provided a pair of optical fiber cables 110 as shown in FIG. 4, wherein one side optical fiber cable serves to transmit the arc flash detection optical signal and the other side optical fiber cable serves to receive the arc flash optical signal received through the lateral periphery of the optical fiber cable and the arc flash optical signal reflected from the lens part 120, but of course, a single optical fiber cable for transmitting and receiving the optical signals may be provided in the arc flash detection device 100.

According to the present invention, each optical fiber cable 110 is desirably made of a plastic optical fiber having a high core ratio so as to detect the light generated by the arc flash, through one strand of optical fiber. For example, it is desirable that the plastic optical fiber has the ratio of core to cladding of 980 to 1000 μm. That is, the plastic optical fiber includes a core made of high purity polymethyl methacrylate PMMA and a thin clad layer made of fluorine polymethyl methacrylate F-PMMA, and desirably, the plastic optical fiber is a step-index profile fiber wherein since the refractive index of the clad layer is lower than that of the core, the light incident from one side end of the optical fiber is totally reflected on the connection surface between the core and the clad layer and advances to the other end of the optical fiber through the core, while having a light emitting function on the lateral periphery thereof.

That is, transmission losses in wavelengths of the plastic optical fiber of the optical fiber cable 100 applied to the present invention, that is, the loss in absorption of ultraviolet rays and the loss caused by a material are generated, and in case of an arc flash having wavelength spectrums of bandwidths of 325 nm, 380 nm, and 525 nm, sensing the bandwidth of 525 nm is effective when considering the transmission loss in the optical fiber. So as to prevent the sensor from being malfunctioned, however, a filter through which only the wavelength having the bandwidth of 525 nm is transmitted is disposed on a PD window, and contrarily, a filter through which the wavelength having the bandwidth of 525 nm is cut off is disposed on a surrounding light source like an indoor lamp disposed in the power receiving and distributing facility.

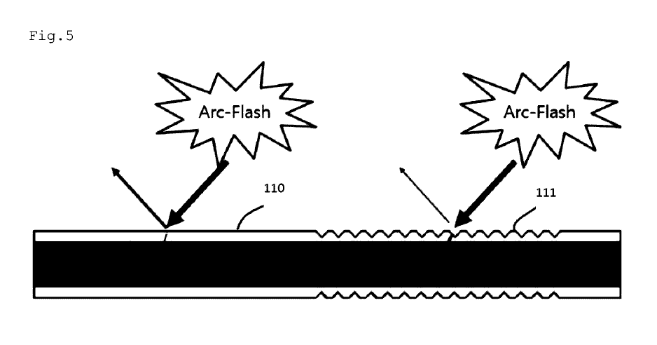

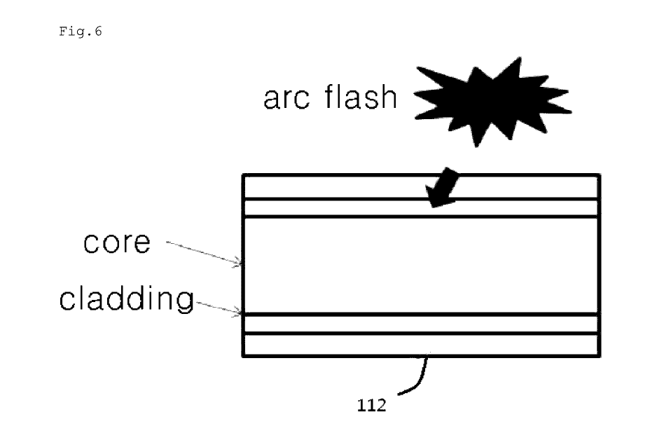

Referring to FIGS. 5 and 6, the structure for receiving the light from the lateral periphery of the optical fiber cable 110 in the arc flash detection device according to the present invention will be described.

FIG. 5 is a sectional view showing an example of a structure for receiving light from the lateral periphery of the optical fiber cable in the arc flash detection device according to the present invention, and FIG. 6 is a sectional view showing another example of a structure for receiving light from the lateral periphery of the optical fiber cable in the arc flash detection device according to the present invention.

As shown in FIG. 5, a scratched fine pattern 111 is formed on one end of the optical fiber cable 110, that is, a portion close to the power receiving and distributing facility, for example, a portion of the optical fiber cable 110 close to the lens part 120.

The formation of the fine pattern 111 on the plastic optical fiber improves the light receiving efficiency on the lateral periphery of the optical fiber.

So as to enhance the receiving rate of the arc light incident from the outside, that is, the fine pattern 111 is formed in the range of a given μm wherein propagation loss of the optical fiber is not increased.

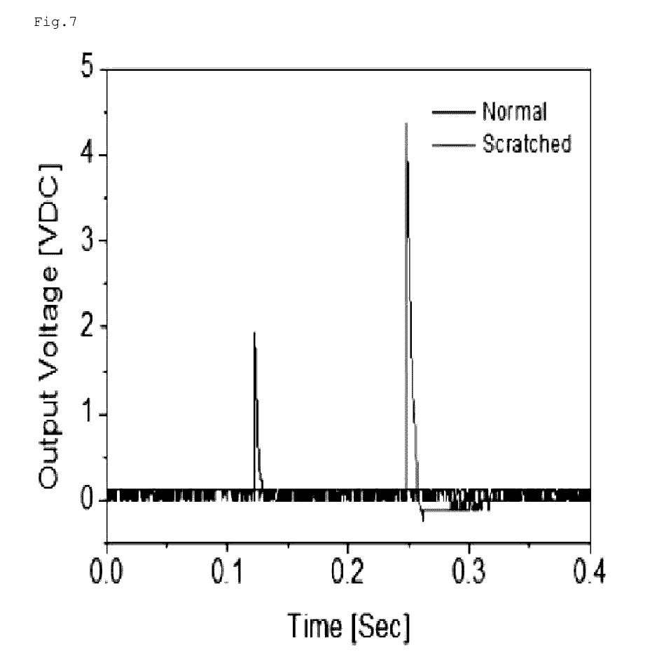

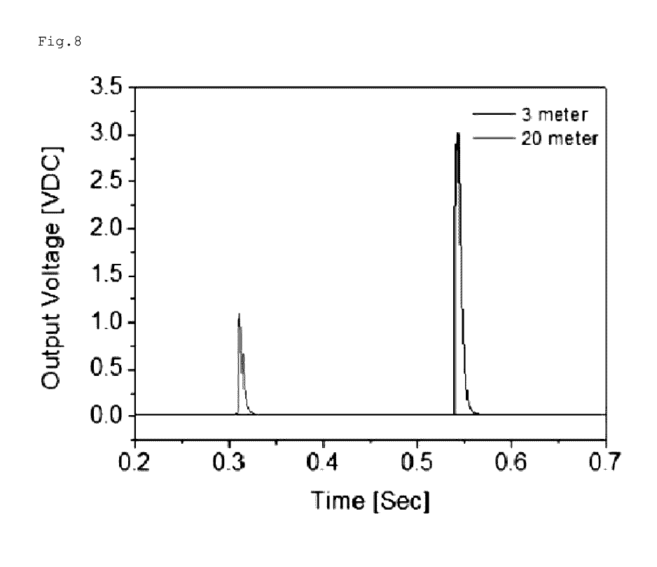

The comparison results between the output voltages for lateral incident light according to the arc flash discharge at the same position as each other are shown in FIGS. 7 and 8.

FIG. 7 is a graph showing the comparison between output voltages of an optical fiber cable being in a normal state and an optical fiber cable having a scratched fine pattern formed thereon, on a point of 20 m, and FIG. 8 is a graph showing the comparison between output voltages of the arc flash discharge according to the distance between the optical fiber and the arc light source.

According to the present invention, as shown in FIG. 8, it can be appreciated that the detection distance is improved through the formation of the fine pattern 111 on the surface of the optical fiber.

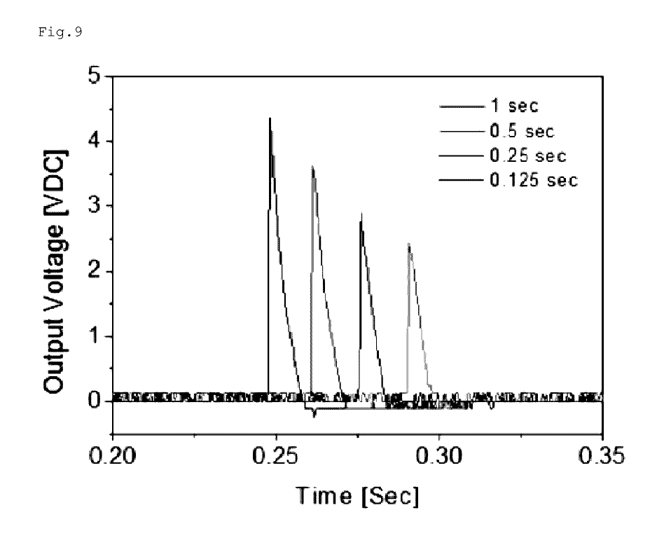

The comparison results between the output voltages for lateral incident light according to the arc flash discharge time through the scratched plastic optical fiber are shown in FIG. 9.

FIG. 9 is a graph showing the comparison results of optical detection voltages according to arc discharge time.

According to the present invention, as shown in FIG. 9, it can be appreciated that since the sizes of the output voltages in the arc flash detection device are varied in accordance with the arc discharge time, cutoff control time is desirably set, while additionally considering arc discharge maintaining time and arc discharge strength.

On the other hand, as shown in FIG. 6, the optical fiber cable 110 in the arc flash detection device according to the present invention further includes a coating layer 112 formed by applying an ultraviolet absorbing material to the clad layer thereof so as to improve arc flash sensitivity through the ultraviolet absorbing material.

If light is radiated on polymer molecules, generally, the molecules absorb the light energy, so that an electron motion occurs to rotate the molecules or to resonate and vibrate interatomic bonding. If the electron motion occurs, the light is absorbed to decrease light transmission.

The light absorption is largely classified into electron transition absorption occurring in an ultraviolet region and molecule vibration absorption occurring in an infrared region. If a material with which the electron transition absorption occurs well is applied to the plastic optical fiber, the sensing efficiency of the arc flash can be greatly improved.

Additionally, the electron transition absorption will be described.

Since solar light is generally used as an optical material, transmittance in a visible light region is first important. The transmittance is governed by the ultraviolet absorption, that is, the electron transition absorption, based generally on the optical excitation of electrons, and the electron transition absorption is dependent upon bonding forces of the atoms constituting the optical material.

Since electrons in polymers made by single bonding on the basis of δ electrons having strong bonding forces are restricted to each other, it is difficult that the electron motion occurs and the light absorption is low. However, if light is reflected on the polymers having double bonding of π electrons having weak bonding in molecule chains, the electron motion occurs and the energy levels of electrons are varied, thus showing the light absorption.

The representative examples of the electron transition absorption include the transition from π to π* by double bonding of benzene ring and azo group, the transition from n to π* by CO group, and the transition from n to δ* based on SH bonding.

Further, the ultraviolet wavelengths are divided into UV-A of 400 to 320 nm, UV-B of 320 to 280 nm, and UV-C of less than 280 nm.

The arc flash spectrum wavelengths are 325 nm, 380 nm, and 525 nm.

The ultraviolet absorbing material used to coat the sensor includes benzophenone, benzotriazole, salicylate, cyanoacrylate, oxanilide, hindered amine, and metal complex optical stabilizers.

The lens part 120 has a structure applied to a typical optical detector disclosed in the above-mentioned Patent documents, and a detailed explanation on the lens part 120 will be avoided for the brevity of the description.

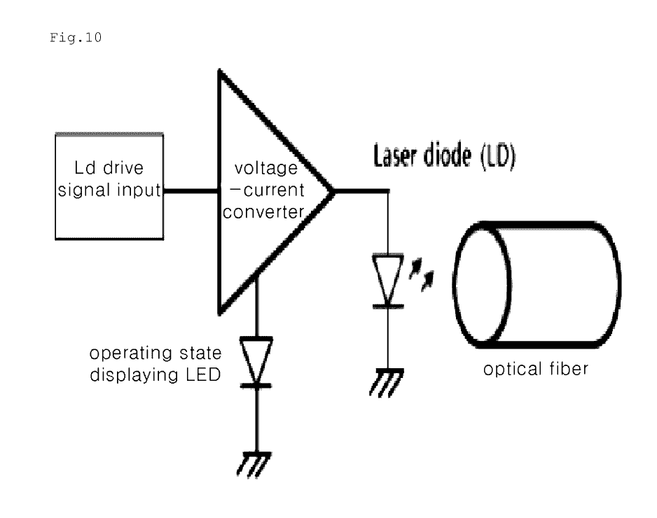

Next, a configuration of the optical detection part 130 applied to the arc flash detection device according to the present invention will be explained with reference to FIGS. 10 to 17.

According to the characteristics of the present invention, the optical detection part 130 in the arc flash detection device according to the present invention includes a line sensor and a loop sensor.

That is, the optical detection part 130 applied to the arc flash detection device according to the present invention includes the line sensor, to which the optical fiber cable is connected, for detecting the arc flash on the end of the optical fiber cable, and the loop sensor for detecting the arc flash optical signal incident on the lateral periphery of the optical fiber cable disposed on the continuous section and transmitting the detected arc flash optical signal to a relay.

As the arc sensor formed of one sensor per sensor channel, there are a point sensor formed only as an optical detector and a line sensor for detecting an arc flash from the end of the optical fiber connected thereto, but when considering electromagnetic effects, according to the present invention, the line sensor is applied if installed in the interior of the distribution panel.

The loop sensor is a sensor that reversely utilizes a phenomenon wherein an optical signal having weak strength is escaped through the lateral periphery of the optical fiber when the optical signal advances through the optical fiber.

The phenomenon is optimized through the plastic optical fiber, and according to the present invention, the optical fiber adequate to the loop sensor is chosen. In the conventional practice, further, a specifically manufactured optical fiber loop is made by coating a polymer material having light absorbing properties onto optical fiber strands, but according to the present invention, only one strand of plastic optical fiber having a larger core size than the cladding is used.

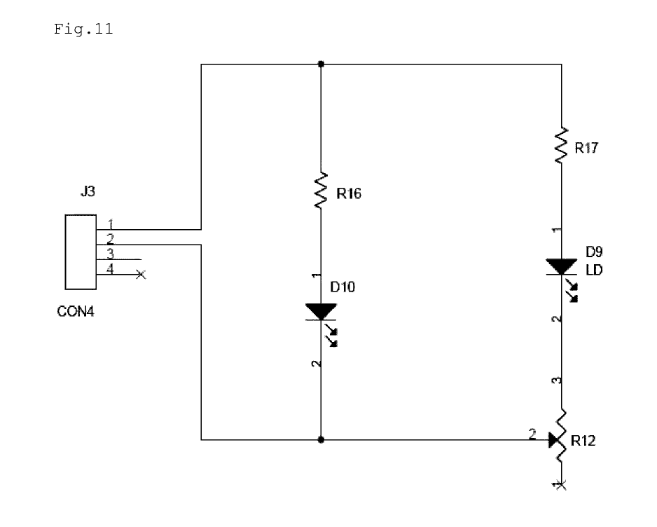

FIG. 10 is a block diagram showing an optical transmitter disposed in the optical detection part of the arc flash detection device according to the present invention, and FIG. 11 is a circuit diagram showing the optical transmitter in the arc flash loop sensor.

The optical cable is formed of the plastic optical fiber, and the optical transmitter for a loop sensor optical trip is configured to detect the optical strength of the arc flash formed in a visible light region.

The circuit diagram of FIG. 11 shows a TO-CAN type LD drive circuit.

As shown in FIGS. 10 and 11, if a laser diode LD drive signal is inputted to a controller (not shown) through a terminal CON4, an operating current is supplied to an operating state displaying LED D10 and a laser diode D9 through voltage-current converters R16 and R17. Through the supply of the operating current, the operating state displaying LED D10 is turned on to display the operating state of the optical transmitter, and the laser diode D9 transmits the light corresponding to the operating current to the optical fiber cable 110.

Under the above-mentioned structure, transmission and trip can be optimized.

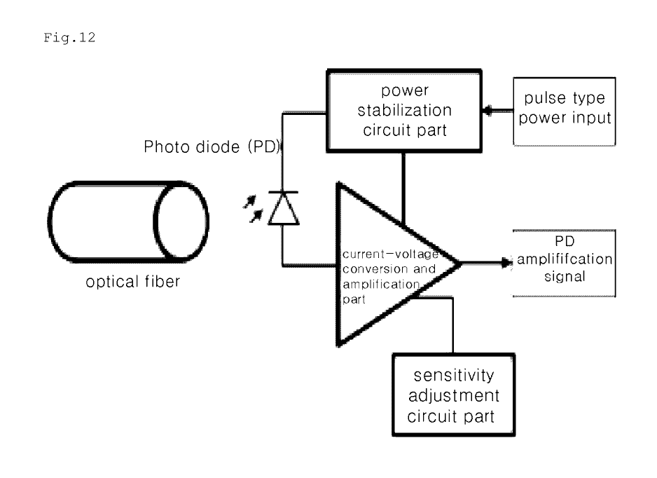

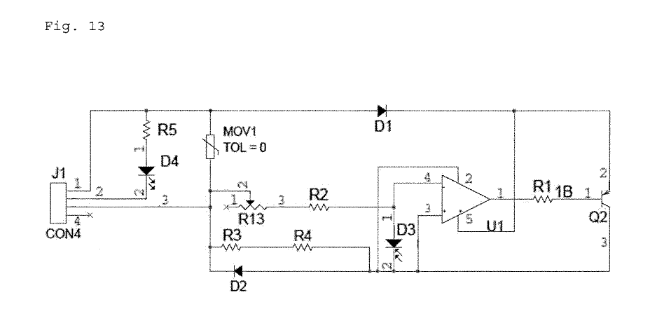

FIG. 12 is a block diagram showing an optical receiver having a photodiode for detecting the light on the lateral periphery of the optical fiber according to the present invention, and FIG. 13 is a circuit diagram showing the optical receiver in the arc flash loop sensor.

As shown in FIGS. 12 and 13, the light received through the fine pattern 111 or the coating layer 112 of the optical fiber cable 110 as shown in FIGS. 5 and 6 is detected through a photo diode PD and amplified in a current-voltage conversion and amplification part, and the PD amplification signal is outputted. The amplification state of the current-voltage conversion and amplification part is controlled by a power stabilization circuit part to which a pulse type power is inputted and by a sensitivity adjustment circuit part.

With the formation of the receiver circuit of the photo diode PD as shown in FIGS. 12 and 13, the sensor sensitivity and the trip level can be optimized.

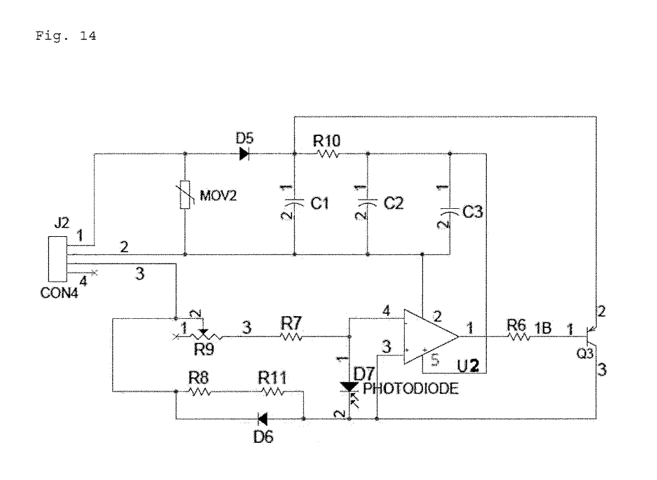

FIG. 14 is a circuit diagram showing the arc flash line sensor.

That is, the line sensor as shown in FIG. 14 is an arc flash photo diode-based sensor, and the circuit of FIG. 14 is a circuit of an optical receiver configured to detect the optical strength of the arc flash in the wavelength region of 325 to 450 nm through the UV region filtering on a TO-CAN PD window.

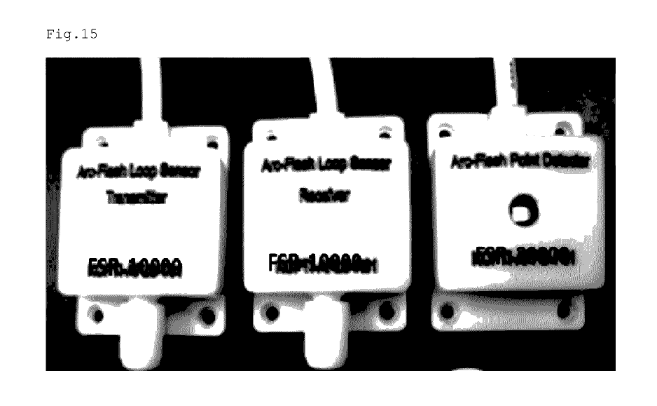

FIG. 15 is a photograph showing the products of the arc flash loop sensor and the arc flash line sensor made according to the circuits of FIGS. 11, 13 and 14.

When compared with the line sensor, the loop sensor is more dependent upon the light receiving efficiency on the lateral periphery of the optical fiber, so that after the sensitivity of the photo diode PD is maximized, resistance values are varied to trace a minimum resistance value for 10 klux.

As shown in FIG. 15, the sensitivity of the loop sensor is maximized, so that characteristics having a large dynamic range of 10 to 45 klux are provided. After tests are carried out, the line sensor and the loop sensor satisfy the condition of the large dynamic range of 10 to 45 klux, and the reaction to the arc light is finished within maximum 2.5 msec. If the method for optimizing the sensitivity of the photo diode is used together with the method for forming the fine pattern on the surface of the plastic optical fiber, further, the above-mentioned results are very effective.

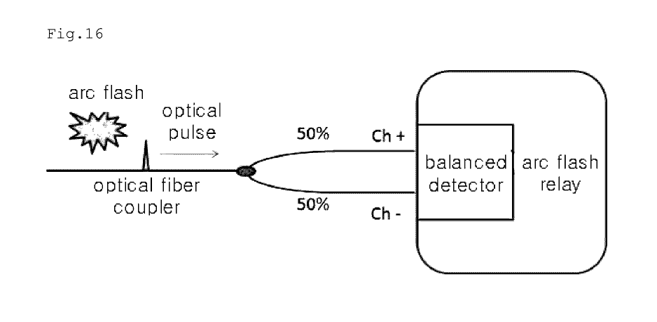

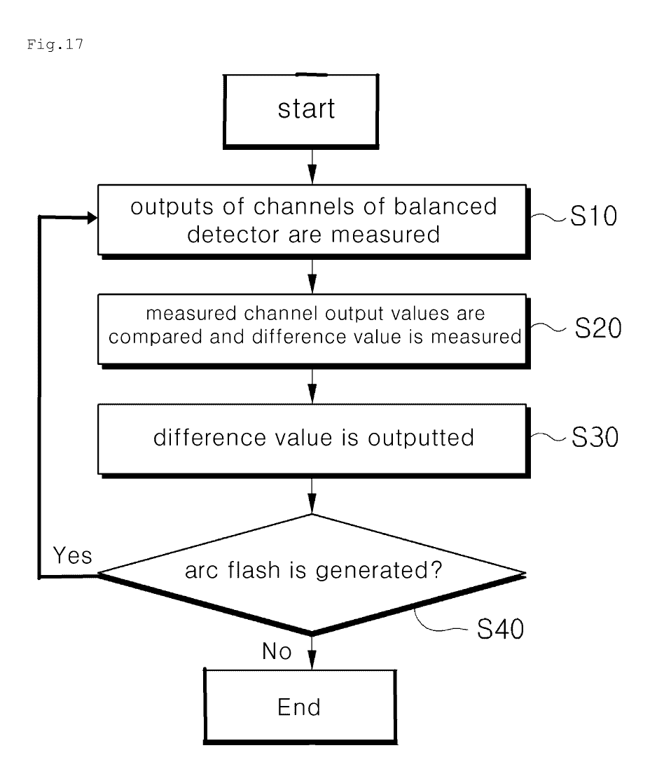

Next, an explanation on an arc flash optical fiber sensor according to the present invention will be given with reference to FIGS. 16 and 17.

FIG. 16 is a diagram showing a basic configuration of an arc flash detection device using a balanced detector, and FIG. 17 is a flowchart showing an arc flash detection algorism using the balanced detector of FIG. 16.

The balanced detector as shown in FIG. 16 includes a first optical detector and a second optical detector having the opposite phase to the first optical detector.

That is, the arc flash detection using the balanced detector is effective in noise suppression and sensitivity improvement.

As shown in FIG. 16, the balanced detector has photo diodes having the same characteristics as each other, from which the outputs of Ch+ and Ch− are the same as each other and the phases are different from each other, so that it is effective in the detection of a small-sized signal through noise suppression.

The balanced detector divides the optical pulse generated by the arc flash by 50% through a multi-mode optical fiber distributer and inputs the divided optical pulses to the Ch+ and Ch−. After that, if the electric signals from the respective photo diodes are superposed on each other, noise cancellation and a signal to noise ratio SNR are improved.

Accordingly, the improvement in signal contrast for the very weak optical signal incident through the optical fiber surface as shown in FIGS. 5 and 6 can be achieved, without having any amplification through an avalanche photo diode APD or a transimpedance amplifier TIA.

Typically, it is impossible to detect a small-sized signal due to noise, but with the adoption of the balanced detector according to the present invention, it is possible to suppress noise and it is very effective in the regulation of a threshold voltage determining whether an arc flash is generated and in signal processing.

Next, the arc flash detection using the balanced detector will be explained with reference to FIG. 17.

First, the outputs of the channels Ch+ and Ch− of the balanced detector as shown in FIG. 16 are measured at step S10.

After that, the measured channel values measured at step S10 are compared with each other by means of a controller (not shown) and a difference value between the output values of the channels is measured at step S20. Next, the difference value measured at step S20 is outputted at step S30 and compared with previously set optical receiving sensitivity, and if it is more than the set sensitivity, it is determined at step S40 that an arc flash is generated.

If the different value is within the set sensitivity, the detection is finished.

On the other hand, if it is determined at step S40 that an arc flash has been generated, the returning to the step S10 is carried out to repeat the above-mentioned steps.

With the adoption of the balanced detector, accordingly, it can be precisely and rapidly determined whether the arc flash is generated or not.

As described above, the arc flash detection device and method according to the present invention is configured wherein it is determined whether the arc flash is generated according to the arc flash optical signal received through the lateral periphery of the optical fiber cable and the arc flash optical signal reflected on the lens part, thus accurately detecting the generation of the arc flash in the power receiving and distributing facility.

Moreover, the arc flash detection device and method according to the present invention is configured to utilize the arc flash optical signal received through the lateral periphery of the optical fiber cable, thus improving the detection distance.

Additionally, the arc flash detection device and method according to the present invention is configured to utilize the arc flash optical signal received through the lateral periphery of the optical fiber cable, thus detecting the reaction to the arc flash within a short period of time, optimizing the sensitivity in the optical detection part, and in advance preventing the generation of safety accidents in the power receiving and distributing facility.

Further, the arc flash detection device and method according to the present invention is capable of preventing power failure from occurring unnecessarily and increasing the reliability of the maintenance of the power receiving and distributing facility.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. An arc flash detection device for detecting the generation of an arc flash in a power receiving and distributing facility in which a power receiving panel, a distribution panel, a motor control panel, a high voltage panel, a low voltage panel, and a panel board are disposed and for generating a trip signal upon the generation of the arc flash, comprising:
optical fiber cables for transmitting an arc flash detection optical signal and receiving an arc flash optical signal converted by the arc flash;
a lens part having a reflection element adapted to reflect the arc flash detection optical signal transmitted through the optical fiber cables and the arc flash optical signal converted by the arc flash if the arc flash is generated; and
an optical detection part for transmitting the arc flash detection optical signal through the optical fiber cables and comparing the arc flash optical signal received through the lateral periphery of one side optical fiber cable and the arc flash optical signal reflected on the lens part with the arc flash detection optical signal to output an arc flash generation signal as a difference signal between the compared results, the optical detection part comprising a line sensor, to which each optical fiber cable is connected, for detecting the arc flash on the end of the optical fiber cable, and a loop sensor for detecting the arc flash optical signal incident on the lateral periphery of the optical fiber cable disposed on the continuous section and transmitting the detected arc flash optical signal to a relay, the loop sensor having an optical receiver for receiving the arc flash optical signal through the lateral periphery of the optical fiber, and each optical fiber cable being scratched on one end thereof to form a fine pattern therealong.

2. The arc flash detection device according to claim 1, wherein each optical fiber cable is one strand of optical fiber made of a plastic optical fiber having a larger core than cladding.

3. The arc flash detection device according to claim 2, wherein each optical fiber cable has an ultraviolet absorbing material applied to the cladding thereof.

4. The arc flash detection device according to claim 1, wherein the optical detection part comprises a first optical detector and a second optical detector having the opposite phase to the first optical detector.
